(19) United States
(12) Patent Application Publication
(10) Pub. No.: US 2021/0334173 A1
(43) Pub. Date: Oct. 28, 2021

(54) STORAGE DEVICE AND METHOD OF OPERATING THE SAME

(71) Applicant: SK hynix Inc., Icheon (KR)

(72) Inventor: Ji Hoon HWANG, Icheon (KR)

(21) Appl. No.: 17/062,964

(22) Filed: Oct. 5, 2020

(30) Foreign Application Priority Data
Apr. 24, 2020 (KR) 10-2020-0049944

(51) Int. Cl. G06F 11/14; G06F 11/07; G06F 11/30; G06F 3/06

(52) U.S. Cl. CPC G06F 11/1469; G06F 11/1461; G06F 11/1451; G06F 11/0772; G06F 3/0683; G06F 3/0619; G06F 3/0631; G06F 3/0659; G06F 3/064; G06F 11/3034

(57) ABSTRACT

The present technology relates to an electronic device. A storage device according to the present technology includes a plurality of memory devices and a memory controller. Each of the plurality of memory devices includes a plurality of memory blocks. The memory controller detects a defective memory device among the plurality of memory devices and allocates normal blocks included in the defective memory device to an over-provisioning area used to perform a background operation on the plurality of memory devices.

### CROSS-REFERENCE TO RELATED APPLICATION

The present application claims priority under 35 U.S.C. § 119(a) to Korean patent application number 10-2020-0049944, filed on Apr. 24, 2020, in the Korean Intellectual Property Office, the entire disclosure of which is incorporated herein by reference.

### BACKGROUND

### 1. Field of Invention

Embodiments of the present disclosure relate to an electronic device, and more particularly, to a storage device and a method of operating the same.

### 2. Description of Related Art

A storage device is a device that stores data under the control of a host device such as a computer, a smartphone, or the like. The storage device may include a memory device in which data is stored and a memory controller controlling the memory device. The memory device may include a volatile memory device and a non-volatile memory device.

The volatile memory device is a device that stores data only when power is supplied thereto and loses the stored data when the power supply is cut off. The volatile memory device includes a static random access memory (SRAM), a dynamic random access memory (DRAM), and the like.

The non-volatile memory device is a device that does not lose data even though power supply is cut off. The non-volatile memory device may include a read only memory (ROM), a programmable ROM (PROM), an electrically programmable ROM (EPROM), an electrically erasable and programmable ROM (EEPROM), a flash memory, and the like.

### SUMMARY

Embodiments of the present disclosure provide a storage device having improved storage area management performance, and a method of operating the same.

A storage device according to an embodiment of the present disclosure includes a plurality of memory devices and a memory controller. Each of the plurality of memory devices includes a plurality of memory blocks. The memory controller detects a defective memory device among the plurality of memory devices and allocates normal blocks included in the defective memory device to an over-provisioning area used to perform a background operation on the plurality of memory devices.

A method of operating a storage device including a plurality of memory devices each including a plurality of memory blocks according to an embodiment of the present disclosure includes detecting a defective memory device satisfying a defective condition among the plurality of memory devices, and allocating normal blocks included in the defective memory device to an over-provisioning area used to perform a background operation on the plurality of memory devices.

According to the present technology, the storage device having improved storage area management performance, and the method of operating the same are provided.

### BRIEF DESCRIPTION OF THE DRAWINGS

FIG. 1 is a diagram illustrating a storage device according to an embodiment of the present disclosure.

FIG. 2 is a diagram illustrating a memory device of FIG. 1.

FIG. 3 is a diagram illustrating a memory cell array of FIG. 2.

FIG. 4 is a diagram illustrating a method in which one memory controller controls a plurality of memory devices.

FIG. 5 is a diagram illustrating a super block according to an embodiment.

FIG. 6 is a diagram illustrating normal blocks of a defective memory device according to an embodiment.

FIG. 7 is a diagram illustrating a memory controller of FIG. 1 according to an embodiment.

FIG. 8 is a diagram illustrating a block information storage of FIG. 7.

FIG. 9 is a flowchart for describing an operation of a storage device according to an embodiment.

FIG. 10 is a flowchart for describing an operation of detecting a defective memory device according to a first embodiment.

FIG. 11 is a flowchart for describing an operation of detecting a defective memory device according to a second embodiment.

FIG. 12 is a flowchart illustrating an operation of detecting a defective memory device according to a third embodiment.

FIG. 13 is a diagram illustrating the memory controller of FIG. 1 according to another embodiment.

FIG. 14 is a block diagram illustrating a memory card system to which the storage device according to an embodiment of the present disclosure is applied.

FIG. 15 is a block diagram illustrating a solid state drive (SSD) system to which the storage device according to an embodiment of the present disclosure is applied.

FIG. 16 is a block diagram illustrating a user system to which the storage device according to an embodiment of the present disclosure is applied.

### DETAILED DESCRIPTION

Specific structural or functional descriptions of embodiments according to the concept which are disclosed in the present specification or application are illustrated only to describe the embodiments according to the concept of the present disclosure. The embodiments according to the concept of the present disclosure may be carried out in various forms and the descriptions are not limited to the embodiments described in the present specification or application.

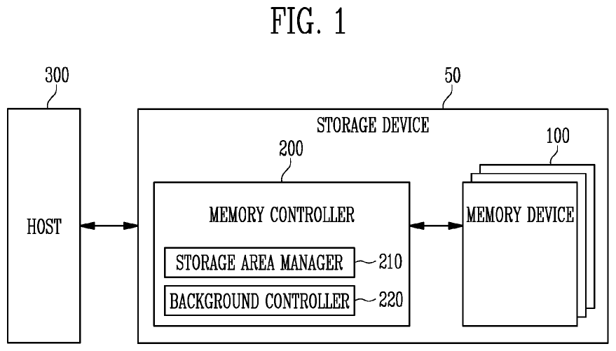

FIG. 1 is a diagram illustrating a storage device 50 according to an embodiment of the present disclosure.

Referring to FIG. 1, the storage device 50 may include a memory device 100 and a memory controller 200 for controlling an operation of the memory device 100. The storage device 50 is a device that stores data under the control of a host 300 such as a cellular phone, a smartphone, an MP3 player, a laptop computer, a desktop computer, a game player, a TV, a tablet PC, an in-vehicle infotainment system, or the like.

The storage device 50 may be one of various types of storage devices according to a host interface that is a communication method with the host 300. For example, the storage device 50 may be configured as any one of various types of storage devices such as an SSD, a multimedia card in a form of an MMC, an eMMC, an RS-MMC, a micro-MMC, or the like, a secure digital card in a form of an SD, a mini-SD, a micro-SD, or the like, a universal serial bus (USB) storage device, a universal flash storage (UFS) device, a personal computer memory card international association (PCMCIA) card type storage device, a peripheral component interconnection (PCI) card type storage device, a PCI express (PCI-E) card type storage device, a compact flash (CF) card, a smart media card, a memory stick, and so on.

The storage device 50 may be manufactured as any one of various types of packages such as a package on package (POP), a system in package (SIP), a system on chip (SOC), a multi-chip package (MCP), a chip on board (COB), a wafer-level fabricated package (WFP), a wafer-level stack package (WSP), and so on.

The memory device 100 may store data. The memory device 100 may operate under the control of the memory controller 200. The memory device 100 may include a memory cell array including a plurality of memory cells that store data.

Each of the memory cells may be configured as a single level cell (SLC) storing one-bit data, a multi-level cell (MLC) storing two-bit data, a triple level cell (TLC) storing three-bit data, or a quad level cell (QLC) storing four-bit data.

The memory cell array may include a plurality of memory blocks. Each of the memory blocks may include a plurality of memory cells. One memory block may include a plurality of pages. In an embodiment, a page may be a unit for storing data in the memory device 100 or reading out data stored in the memory device 100.

A memory block may be a unit for erasing data stored in the memory device 100. In an embodiment, the memory device 100 may be a double data rate synchronous dynamic random access memory (DDR SDRAM), a low power double data rate4 (LPDDR4) SDRAM, a graphics double data rate (GDDR) SDRAM, a low power DDR (LPDDR), a Rambus dynamic random access memory (RDRAM), a NAND flash memory, a vertical NAND flash memory, a NOR flash memory device, a resistive random access memory (RRAM), a phase-change memory (PRAM), a magnetoresistive random access memory (MRAM), a ferroelectric random access memory (FRAM), a spin transfer torque random access memory (STT-RAM), or the like. In the present specification, for convenience of description, it is assumed that the memory device 100 is a NAND flash memory.

The memory device 100 is configured to receive a command and an address from the memory controller 200 and access a target area in the memory cell array that is selected by the address. That is, the memory device 100 may perform an operation instructed by the command on the target area selected by the address. For example, the memory device 100 may perform a write operation (or program operation), a read operation, and an erase operation under the control of the memory controller 200. During the program operation, the memory device 100 may program data to the target area selected by the address. During the read operation, the memory device 100 may read data from the target area selected by the address. During the erase operation, the memory device 100 may erase data stored in the target area selected by the address.

In an embodiment, the memory device 100 may include a user area and an over-provisioning area. The user area stores user data. The over-provisioning area is a spare area for maintaining performance of the storage device 50. The user area may be used as a space for storing the user data received from the host 300. The over-provisioning area may be used as a spare space for temporarily storing data to perform a background operation such as wear-leveling, garbage collection, read reclaim, or the like.

In an embodiment, a plurality of memory blocks included in the memory device 100 may be classified into a normal block capable of storing data and a bad block that is unusable. A normal block may be allocated to the user area or the over-provisioning area.

In an embodiment, normal blocks included in a memory device that is detected as a defective memory device among the plurality of memory devices 100 controlled by the memory controller 200 may be allocated to the over-provisioning area.

The memory controller 200 controls an overall operation of the storage device 50.

When power is supplied to the storage device 50, the memory controller 200 may execute firmware FW. When the memory device 100 is a flash memory device, the memory controller 200 may operate firmware such as a flash translation layer (FTL) for controlling communication between the host 300 and the memory device 100.

In an embodiment, the memory controller 200 may receive data and a logical block address (LBA) from the host 300 and convert the logical block address (LBA) into a physical block address (PBA) indicating memory cells of the memory device 100 in which the data is to be stored.

The memory controller 200 may control the memory device 100 to perform the program operation, the read operation, or the erase operation in response to a request from the host 300. During the program operation, the memory controller 200 may provide a write command, a physical block address, and write data to the memory device 100 in response to a write request received from the host 300. During the read operation, the memory controller 200 may provide a read command and a physical block address to the memory device 100 in response to a read request received from the host 300. During the erase operation, the memory controller 200 may provide an erase command and a physical block address to the memory device 100 in response to an erase request received from the host 300.

In an embodiment, the memory controller 200 may generate and transmit a command, an address, and data to the memory device 100 regardless of whether there is a request received from the host 300. For example, the memory controller 200 may provide a command, an address, and data to the memory device 100 so as to perform a background operation such as a program operation for wear leveling, a program operation for garbage collection, or the like.

In an embodiment, the memory controller 200 may control a plurality of memory devices 100. In this case, the memory controller 200 may control the plurality of memory devices 100 according to an interleaving method so as to improve operation performance. The interleaving method may be an operation method for overlapping operation periods of the plurality of memory devices 100.

In an embodiment, the memory controller 200 may include a storage area manager 210 and a background controller 220. In an embodiment, the storage area manager 210 and the background controller 220 may be implemented using a memory or register and one or more processors.

The storage area manager 210 may detect a defective memory device satisfying a defective condition among the plurality of memory devices 100. Whether the defective condition is satisfied or not may be determined based on a comparison result of the number of bad blocks included in a memory device and a reference number. The reference number may be preset in a manufacturing stage. The reference number may be updated or changed according to a request of the host 300 or a degree at which a lifetime of the storage device 50 is elapsed, in a use stage.

In an embodiment, the storage area manager 210 may detect a defective memory device among the plurality of memory devices 100 in a test stage. At this time, a bad block may be determined based on a manufacturing bad block (MBB) that has been made in a manufacturing process.

In an embodiment, the storage area manager 210 may detect a defective memory device in a use stage of the plurality of memory devices 100. At this time, the bad block may be determined based on a growing bad block (GBB) that is generated as a usage time of each of the plurality of memory devices 100 is getting longer.

The storage area manager 210 may allocate normal blocks included in the plurality of memory devices 100 to the user area or the over-provisioning area. A ratio at which the normal blocks are allocated to the user area and the over-provisioning may be variously determined.

In an embodiment, the storage area manager 210 may allocate normal blocks included in a defective memory device to the over-provisioning area.

The background controller 220 may control the plurality of memory devices 100 to perform a background operation. In an embodiment, the background controller 220 may perform the background operation on the plurality of memory devices 100 using the normal blocks included in the defective memory device. For example, the normal blocks in the defective memory device are used to store data received from a normal memory device temporarily. The temporarily stored data is returned to the normal memory device.

In an embodiment, the background operation may include wear leveling, garbage collection, read reclaim, or the like.

In an embodiment, the background controller 220 may control a backup operation of storing user data, which is stored in the normal blocks included in the defective memory device, in a normal memory device other than the defective memory device among the plurality of memory devices 100. In an embodiment, after the user data, which is stored in the normal blocks included in the defective memory device, is backed up to the normal memory device, the normal blocks included in the defective memory device may be allocated to the over-provisioning area.

The host 300 may communicate with the storage device 50 using at least one of various communication methods such as a universal serial bus (USB), a serial AT attachment (SATA), a serial attached SCSI (SAS), a high speed interchip (HSIC), a small computer system interface (SCSI), a peripheral component interconnection (PCI), a PCI express (PCIe), a nonvolatile memory express (NVMe), a universal flash storage (UFS), a secure digital (SD), a multimedia card (MMC), an embedded MMC (eMMC), a dual in-line memory module (DIMM), a registered DIMM (RDIMM), a load reduced DIMM (LRDIMM), and so on.

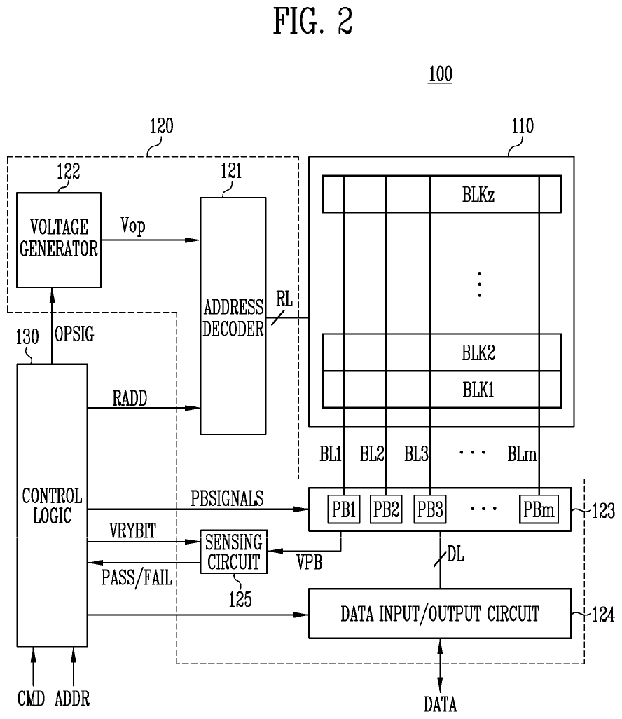

FIG. 2 is a diagram illustrating the memory device 100 of FIG. 1 according to an embodiment of the present disclosure.

Referring to FIG. 2, the memory device 100 may include a memory cell array 110, a peripheral circuit 120, and a control logic 130.

The memory cell array 110 includes a plurality of memory blocks BLK1 to BLKz. The plurality of memory blocks BLK1 to BLKz are connected to an address decoder 121 through row lines RL. The plurality of memory blocks BLK1 to BLKz are connected to a read and write circuit 123 through bit lines BL1 to BLm. Each of the plurality of memory blocks BLK1 to BLKz includes a plurality of memory cells. In an embodiment, the plurality of memory cells are non-volatile memory cells. Memory cells connected to the same word line among the plurality of memory cells are defined as one physical page. That is, the memory cell array 110 is configured of a plurality of physical pages.

According to an embodiment of the present disclosure, each of the plurality of memory blocks BLK1 to BLKz included in the memory cell array 110 may further include a plurality of dummy cells. In a cell string connected to a bit line, at least one of the dummy cells may be connected in series between a drain select transistor and memory cells and between a source select transistor and the memory cells.

Each of the memory cells of the memory device 100 may be configured as a single level cell (SLC) that stores one-bit data, a multi-level cell (MLC) that stores two-bit data, a triple level cell (TLC) that stores three-bit data, or a quad level cell (QLC) that stores four-bit data.

The peripheral circuit 120 may include an address decoder 121, a voltage generator 122, the read and write circuit 123, a data input/output circuit 124, and a sensing circuit 125.

The peripheral circuit 120 drives the memory cell array 110. For example, the peripheral circuit 120 may drive the memory cell array 110 to perform a program operation, a read operation, and an erase operation.

The address decoder 121 is connected to the memory cell array 110 through the row lines RL. The row lines RL may include drain select lines, word lines, source select lines, and a common source line. According to an embodiment of the present disclosure, the word lines may include normal word lines coupled to normal memory cells and dummy word lines coupled to dummy cells. According to an embodiment of the present disclosure, the row lines RL may further include a pipe select line.

The address decoder 121 is configured to operate under the control of the control logic 130. The address decoder 121 receives a row address RADD from the control logic 130.

The address decoder 121 is configured to decode a block address of the received row address RADD. The address decoder 121 selects at least one memory block among the memory blocks BLK1 to BLKz according to the decoded block address. The address decoder 121 may select at least one word line among word lines of the selected memory block according to the row address RADD. The address decoder 121 may apply an operation voltage Vop received from the voltage generator 122 to the selected word line.

During the program operation, the address decoder 121 may apply a program voltage to the selected word line and apply a pass voltage having a level less than that of the program voltage to unselected word lines among the word lines of the selected memory block. During a program verify operation, the address decoder 121 may apply a verify voltage to the selected word line and apply a verify pass voltage having a level greater than that of the verify voltage to the unselected word lines.

During the read operation, the address decoder 121 may apply a read voltage to the selected word line and apply a read pass voltage having a level greater than that of the read voltage to the unselected word lines.

According to an embodiment of the present disclosure, the erase operation of the memory device 100 is performed in memory block units. An address ADDR input to the memory device 100 during the erase operation includes a block address. The address decoder 121 may decode the block address and select at least one memory block according to the decoded block address. During the erase operation, the address decoder 121 may apply a ground voltage to word lines coupled to the selected memory block in order to delete data stored in the selected memory block.

According to an embodiment of the present disclosure, the address decoder 121 may be configured to further decode a column address of the address ADDR. The decoded column address may be transferred to the read and write circuit 123. For example, the address decoder 121 may include a component such as a row decoder, a column decoder, an address buffer, or a combination thereof.

The voltage generator 122 is configured to generate a plurality of operation voltages Vop by using an external power voltage supplied to the memory device 100. The voltage generator 122 operates under the control of the control logic 130.

In an embodiment, the voltage generator 122 may generate an internal power voltage by regulating the external power voltage. The internal power voltage generated by the voltage generator 122 is used as an operation voltage of the memory device 100.

In an embodiment, the voltage generator 122 may generate the plurality of operation voltages Vop using the external power voltage or the internal power voltage. The voltage generator 122 may be configured to generate various voltages required to perform various operations on the memory device 100. For example, the voltage generator 122 may generate one or more of a plurality of erase voltages, a plurality of program voltages, a plurality of pass voltages, a plurality of selection read voltages, a plurality of non-selection read voltages, and so on.

In order to generate the plurality of operation voltages Vop having various voltage levels, the voltage generator 122 may include a plurality of pumping capacitors that receive the external voltage or the internal voltage and selectively activate the plurality of pumping capacitors under the control of the control logic 130 to generate the plurality of operation voltages Vop.

The plurality of operation voltages Vop may be supplied to the memory cell array 110 through the address decoder 121.

The read and write circuit 123 includes first to m-th page buffers PB1 to PBm. The first to m-th page buffers PB1 to PBm are connected to the memory cell array 110 through the first to m-th bit lines BL1 to BLm, respectively. The first to m-th page buffers PB1 to PBm operate under the control of the control logic 130.

The first to m-th page buffers PB1 to PBm communicate data DATA with the data input/output circuit 124. During the program operation, the first to m-th page buffers PB1 to PBm receive write data DATA to be stored through the data input/output circuit 124 and data lines DL.

During the program operation, when a program voltage is applied to the selected word line, the first to m-th page buffers PB1 to PBm may transfer the write data DATA received through the data input/output circuit 124 to selected memory cells coupled to the selected word line through the bit lines BL1 to BLm. The memory cells coupled to the selected word line, i.e., memory cells of a selected page, are programmed according to the transferred write data DATA. A memory cell connected to a bit line to which a program permission voltage (for example, a ground voltage) is applied may have an increased threshold voltage. A threshold voltage of a memory cell connected to a bit line to which a program inhibition voltage (for example, a power voltage) is applied may be maintained without being increased. During the program verify operation, the first to m-th page buffers PB1 to PBm read the write data DATA stored in the memory cells from the selected memory cells through the bit lines BL1 to BLm.

During the read operation, the read and write circuit 123 may read data DATA from the memory cells of the selected page through the bit lines BL1 to BLm and store the read data DATA in the first to m-th page buffers PB1 to PBm.

During the erase operation, the read and write circuit 123 may float the bit lines BL1 to BLm. In an embodiment, the read and write circuit 123 may include a column selection circuit.

The data input/output circuit 124 is connected to the first to m-th page buffers PB1 to PBm through the data lines DL. The data input/output circuit 124 operates under the control of the control logic 130.

The data input/output circuit 124 may include a plurality of input/output buffers (not shown) that receive data DATA. During the program operation, the data input/output circuit 124 receives write data DATA to be stored from an external controller (not shown). During the read operation, the data input/output circuit 124 outputs read data DATA transferred from the first to m-th page buffers PB1 to PBm included in the read and write circuit 123 to the external controller.

During the read operation or the program verify operation, the sensing circuit 125 may generate a reference current in response to a signal of a permission bit VRYBIT generated by the control logic 130 and may compare a sensing voltage VPB received from the read and write circuit 123 with a reference voltage generated by the reference current and output a pass signal or a fail signal to the control logic 130 based on a comparison result.

The control logic 130 may be connected to the address decoder 121, the voltage generator 122, the read and write circuit 123, the data input/output circuit 124, and the sensing circuit 125. The control logic 130 may be configured to control all operations of the memory device 100. The control logic 130 may operate in response to a command CMD transferred from an external device.

The control logic 130 may generate various signals in response to the command CMD and the address ADDR to control the peripheral circuit 120. For example, the control logic 130 may generate an operation signal OPSIG, the row address RADD, a read and write circuit control signal PBSIGNALS, and the permission bit VRYBIT in response to the command CMD and the address ADDR. The control logic 130 may output the operation signal OPSIG to the voltage generator 122, the row address RADD to the address decoder 121, the read and write circuit control signal PBSIGNALS to the read and write circuit 123, and the permission bit VRYBIT to the sensing circuit 125. In addition, the control logic 130 may determine whether the program verify operation is passed or failed in response to the pass or fail signal PASS/FAIL output by the sensing circuit 125.

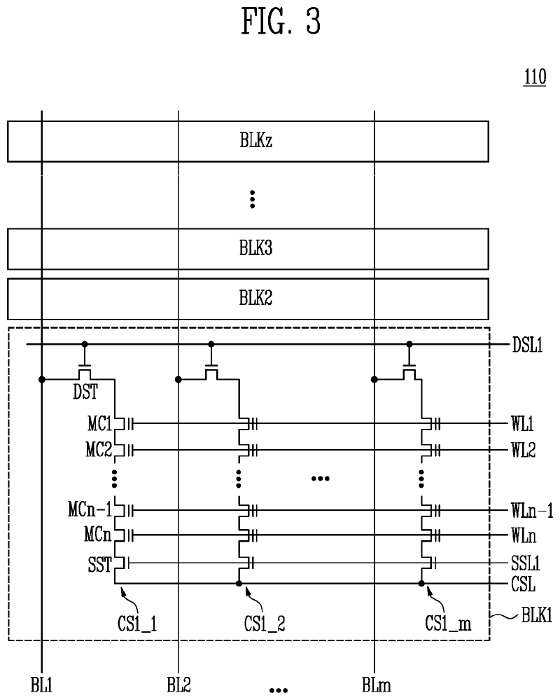

FIG. 3 is a diagram illustrating the memory cell array 110 of FIG. 2 according to an embodiment of the present disclosure.

Referring to FIG. 3, the first to z-th memory blocks BLK1 to BLKz are commonly connected to the first to m-th bit lines BL1 to BLm. For convenience of description, FIG. 3 shows a configuration of the first memory block BLK1 among the plurality of memory blocks BLK1 to BLKz. Each of the remaining memory blocks BLK2 to BLKz is configured similarly to the first memory block BLK1.

The memory block BLK1 may include a plurality of cell strings CS1_1 to CS1_m (m is a positive integer). The first to m-th cell strings CS1_1 to CS1_m are connected to the first to m-th bit lines BL1 to BLm, respectively. Each of the first to m-th cell strings CS1_1 to CS1_m includes a drain select transistor DST, a plurality of memory cells MC1 to MCn connected in series (n is a positive integer), and a source select transistor SST.

Gate terminals of the drain select transistors DST included in the first to m-th cell strings CS1_1 to CS1_m are commonly connected to a drain select line DSL1. Gate terminals of the first to n-th memory cells MC1 to MCn included in each of the first to m-th cell strings CS1_1 to CS1_m are connected to the first to n-th word lines WL1 to WLn, respectively. Gate terminals of the source select transistors SST included in the first to m-th cell strings CS1_1 to CS1_m are commonly connected to a source select line SSL1.

For convenience of description, a structure of a cell string will be described with reference to the first cell string CS1_1 of the plurality of cell strings CS1_1 to CS1_m. However, it will be understood that each of the remaining cell strings CS1_2 to CS1_m is configured similarly to the first cell string CS1_1.

In the first cell string CS1_1, a drain terminal of the drain select transistor DST is connected to the first bit line BL1, and a source terminal of the drain select transistor DST is connected to a drain terminal of the first memory cell MC1. The first to n-th memory cells MC1 to MCn are connected in series with each other. A drain terminal of the source select transistor SST is connected to a source terminal of the n-th memory cell MCn. A source terminal of the source select transistor SST is connected to a common source line CSL. In an embodiment, the common source line CSL may be commonly connected to the first to z-th memory blocks BLK1 to BLKz.

The drain select line DSL1, the first to n-th word lines WL1 to WLn, and the source select line SSL1 are included in row lines RL of FIG. 2. The drain select line DSL1, the first to n-th word lines WL1 to WLn, and the source select line SSL1 are controlled by the address decoder 121. The common source line CSL is controlled by the control logic 130. The first to m-th bit lines BL1 to BLm are controlled by the read and write circuit 123.

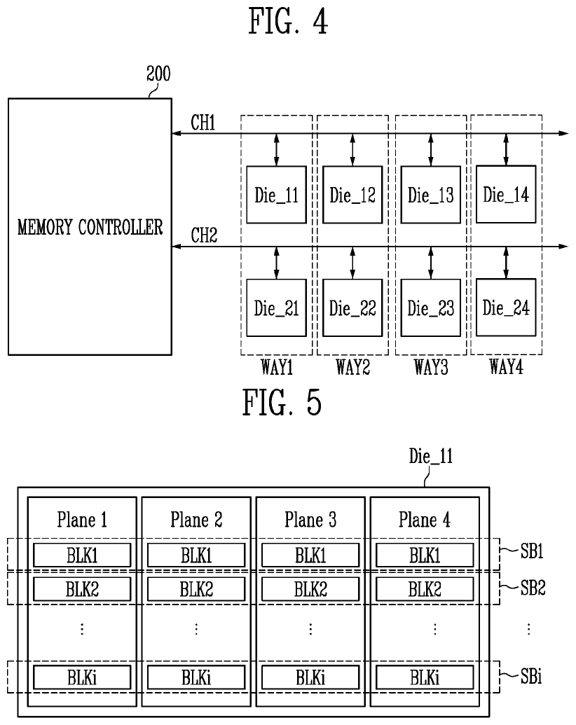

FIG. 4 is a diagram illustrating a method in which one memory controller controls a plurality of memory devices.

Referring to FIG. 4, a memory controller 200 may be connected to a multiplicity of memory devices Die_11 to Die_14 through a first channel CH1 and a multiplicity of memory devices Die_21 to Die_24 through a second channel CH2. The number of channels or the number of memory devices connected to each channel is not limited to the present embodiment.

The memory devices Die_11 to Die_14 may be commonly connected to the first channel CH1. The memory devices Die_11 to Die_14 may communicate with the memory controller 200 through the first channel CH1.

Since the memory devices Die_11 to Die_14 are commonly connected to the first channel CH1, only one of the memory devices Die_11 to Die_14 may communicate with the memory controller 200 at a time. However, internal operations of each of the memory devices Die_11 to Die_14 may be simultaneously performed.

The memory devices Die_21 to Die_24 may be commonly connected to the second channel CH2. The memory devices Die_21 to Die_24 may communicate with the memory controller 200 through the second channel CH2.

Since the memory devices Die_21 to Die_24 are commonly connected to the second channel CH2, only one of the memory devices Die_21 to Die_24 may communicate with the memory controller 200 at a time. However, internal operations of each of the memory devices Die_21 to Die_24 may be simultaneously performed.

A storage device including a plurality of memory devices may improve performance by using a data interleaving method. The data interleaving method may include performing a data read operation or a data write operation by changing a way in which the data read operation or the data write operation is performed in a structure in which two or more ways share one channel. For the data interleaving method, the memory devices may be managed in a unit of a channel and a way. In order to maximize parallelism of the memory devices connected to each channel, the memory controller 200 may dispersedly allocate consecutive logical memory areas into channels and ways.

In FIG. 4, the plurality of memory devices may be configured of four ways WAY1 to WAY4. The first way WAY1 may include the memory devices Die_11 and Die_21. The second way WAY2 may include the memory devices Die_12 and Die_22. The third way WAY3 may include the memory devices Die_13 and Die_23. The fourth way WAY4 may include the memory devices Die_14 and Die_24.

Accordingly, the memory controller 200 may transmit a command, a control signal including an address, and data to the memory device Die_11 through the first channel CH1. While the memory device Die_11 programs the transmitted data to a memory cell included therein, the memory controller 200 may transmit a command, a control signal including an address, and data to the memory device Die_12 since the memory device Die_11 does not use CH1 during an internal operation such as a program operation.

Each of the channels CH1 and CH2 may be a bus of signals shared and used by the memory devices connected thereto.

FIG. 4 illustrates a two channel/four way structure, and the data interleaving method has been described with reference to the two channel/four way structure. However, the data interleaving may be more efficient as the number of channels and the number of ways increase.

FIG. 5 is a diagram illustrating a super block according to an embodiment. The super block will be described with reference to the memory device Die_11 of FIG. 4.

Referring to FIG. 5, the memory device Die_11 may include first to fourth planes Plane 1 to Plane 4. The number of planes included in one memory device is not limited to the present embodiment. One plane may include a plurality of memory blocks BLK1 to BLKi (i is a positive integer).

A plane may be a unit of independently performing a program operation, a read operation, or an erase operation. Therefore, the memory device Die_11 may include the address decoder 121 and the read and write circuit 123, which have been described with reference to FIG. 2, for each plane.

In an embodiment, a super block may include at least two or more memory blocks included in different planes among memory blocks included in a memory device.

Referring to FIG. 5, a first super block SB1 may include first memory blocks BLK1 of the first to fourth planes Plane 1 to Plane 4. A second super block SB2 may include second memory blocks BLK2 of the first to fourth planes Plane 1 to Plane 4. In the same manner, an i-th super block SBi may include i-th memory blocks BLKi of the first to fourth planes Plane 1 to Plane 4. Therefore, the memory device Die_11 may include the first to i-th super blocks SB1 to SBi.

Each super block may include a plurality of stripes (or super pages). A memory controller, e.g., the memory controller 200 of FIG. 4, may store data in the first to fourth planes Plane 1 to Plane 4 and read the stored data, in a stripe unit or a super page unit.

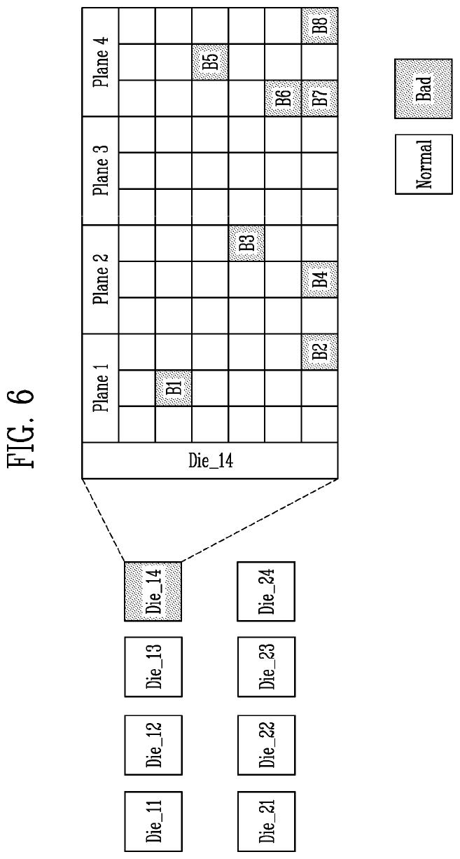

FIG. 6 is a diagram illustrating normal blocks of a defective memory device according to an embodiment.

Referring to FIG. 6, the memory controller 200 described with reference to FIG. 1 may control the plurality of memory devices Die_11 to Die_24 shown in FIG. 4. The number of memory devices controlled by the memory controller 200 is not limited to the present embodiment.

In FIG. 6, the memory device Die_14 may be a defective memory device that satisfies a defective condition. The memory device Die_14 may include first to fourth planes Plane 1 to Plane 4. The number of planes included in the memory device Die_14 and the number of memory blocks included in one plane are not limited to the present embodiment.

In an embodiment, the defective condition may be satisfied when the number of bad blocks included in a memory device is equal to or greater than a reference number. In an embodiment, the reference number may be determined based on a reference ratio of bad blocks to all memory blocks in a reference area.

For example, referring to FIG. 6, the memory device Die_14 may include (18×4=72) memory blocks, each plane including 18 memory blocks. The memory device Die_14 may include eight bad blocks B1 to B8.

Description will be given under an assumption that the reference ratio is 1/9 when the reference area is one memory device. The reference number may be eight that is 1/9 of the 72 memory blocks. Therefore, since the total number of bad blocks, i.e., 8, included in the memory device Die_14 is equal to the reference number, i.e., 8, the memory device Die_14 may be detected as the defective memory device.

In an embodiment, the defective condition may be satisfied when the number of bad blocks included in any one of one or more planes included in one memory device is equal to or greater than a reference number.

For example, each of the plurality of planes Plane 1 to Plane 4 may include 18 memory blocks as illustrated in FIG. 6. The first plane Plane 1 may include two bad blocks B1 and B2. The second plane 2 Plane 2 may include two bad blocks B3 and B4. The fourth plane Plane 4 may include four bad blocks B5, B6, B7, and B8.

Description will be given under an assumption that the reference ratio is 1/6 when the reference area is one plane. The reference number may be three that is 1/6 of the total 18 memory blocks included in the one plane. Therefore, since the total number of bad blocks, i.e., 4, included in the fourth plane Plane 4 is equal to the reference number, i.e., four, the memory device Die_14 may be detected as the defective memory device.

In an embodiment, the defective condition may be satisfied when the number of bad blocks included in any one of one or more super blocks included in one memory device is equal to or greater than a reference number.

As described with reference to FIG. 5, one super block may include a memory block disposed at the same position in each plane in a memory device. Therefore, the super block may include four memory blocks. Description will be given under an assumption that the reference ratio is 1/2. The reference number may be two that is 1/2 of the total four memory blocks included in the one super block.

In FIG. 6, each super block may include four memory blocks included in the first to fourth planes Plane 1 to Plane 4, respectively. The memory device Die_14 includes a super block that includes the two bad blocks B2 and B8 of which positions are the same in the planes Plane 1 and Plane 4. Therefore, the memory device Die_14 including the super block including the two bad blocks B2 and B8 may be detected as the defective memory device since the number of bad blocks, i.e., 2, is equal to the reference number, i.e., two.

In an embodiment, the reference number or the reference ratio of the defective condition may be determined in a manufacturing stage of the storage device 50. In various embodiments, the reference number or the reference ratio of the defective condition may be updated according to a request of the host 300 or the degree at which the lifetime of the storage device 50 is elapsed in the use stage described with reference to FIG. 1. For example, since a probability of occurrence of a bad block increases as the lifetime of the storage device 50 is elapsed, the reference number or the reference ratio may be increased accordingly.

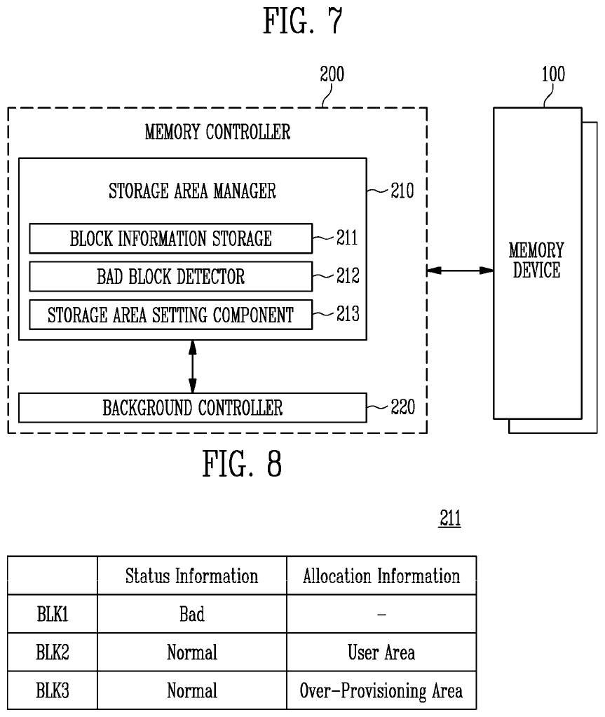

FIG. 7 is a diagram illustrating the memory controller 200 of FIG. 1 according to an embodiment. As shown in FIG. 1, the memory controller 200 includes the storage area manager 210 and the background controller 220.

Referring to FIG. 7, the memory controller 200 may control a plurality of memory devices 100.

Each of the memory devices 100 may include a user area and an over-provisioning area. The user area stores user data, and the over-provisioning area is a spare area for maintaining performance of the storage device 50. The user area may be used as a storage space for storing the user data received from the host 300. The over-provisioning area may be used as a spare storage space that temporarily stores data to perform a background operation such as wear-leveling, garbage collection, or read reclaim.

A plurality of memory blocks included in the memory device 100 may be classified into a normal block capable of storing data and a bad block that is unusable. The normal block may be allocated to the user area or the over-provisioning area.

In an embodiment, the storage area manager 210 may include a block information storage 211, a bad block detector 212, and a storage area setting component 213.

The block information storage 211 may store block information about a plurality of memory blocks included in each of the plurality of memory devices 100.

The block information may include status information indicating whether each memory block is the normal block or the bad block, and allocation information indicating whether the normal block is allocated to the user area or the over-provisioning area. In an embodiment, an initial value of the status information for each memory block may be set to indicate the normal block.

The bad block detector 212 may determine an error uncorrectable block as the bad block when the error uncorrectable block is detected while performing an overall operation on each of the plurality of memory blocks included in each of the plurality of memory devices 100. The overall operation may include a read operation, a program operation, or an erase operation.

When the error uncorrectable block is detected, the bad block detector 212 may update block information corresponding to the error uncorrectable block among the block information on the plurality of memory blocks stored in the block information storage 211. For example, the bad block detector 212 may update the block information so that status information included in the block information corresponding to the error uncorrectable block is changed from the initial value to a value indicating the bad block.

The storage area setting component 213 may detect a defective memory device satisfying a defective condition among the plurality of memory devices 100 based on the block information stored in the block information storage 211. The defective condition may be satisfied when the number of bad blocks included in a reference area is equal to or greater than a reference number. For example, the reference area may be a memory device, a plane, or a super block. The reference area is not limited to the present embodiment and may be variously set.

In an embodiment, the reference number may be preset in a manufacturing stage. The reference number may be updated or changed according to a request of the host 300 or a degree at which a lifetime of the storage device 50 is elapsed in a use stage.

In an embodiment, the storage area setting component 213 may detect the defective memory device based on a result of comparing the number of bad blocks included in one memory device 100 with a first reference number. In another embodiment, the storage area setting component 213 may detect the defective memory device based on a result of comparing the number of bad blocks included in any one of one or more planes included in one memory device 100 with a second reference number. In still another embodiment, the storage area setting component 213 may detect the defective memory device based on a result of comparing the number of bad blocks included in any one of one or more super blocks included in one memory device 100 with a third reference number.

As described with reference to FIG. 6, the reference number may vary according to a range of the reference area for counting the number of bad blocks. In an embodiment, the reference number may be determined based on a reference ratio of the bad blocks to all memory blocks included in the reference area. In an embodiment, the bad block may be determined based on at least one of a manufacturing bad block (MBB) and a growing bad block (GBB).

In an embodiment, the storage area setting component 213 may detect the defective memory device in a test stage for the plurality of memory devices 100. In another embodiment, the storage area setting component 213 may detect the defective memory device in a use stage for the plurality of memory devices 100.

The storage area setting component 213 may allocate the normal blocks included in the plurality of memory devices 100 to the user area or the over-provisioning area. For example, the storage area setting component 213 may update the allocation information corresponding to the normal block stored in the block information storage 211 according to whether the normal block is allocated to the user area or the over-provisioning area.

In an embodiment, the storage area setting component 213 may allocate the normal blocks included in the defective memory device to the over-provisioning area. For example, the storage area setting component 213 may update the block information corresponding to the normal blocks included in the defective memory device among the block information on the plurality of memory blocks stored in the block information storage 211. The storage area setting component 213 may update the block information so that the allocation information included in the block information corresponding to the normal blocks included in the defective memory device indicates the over-provisioning area.

The background controller 220 may control the plurality of memory devices 100 to perform the background operation for the performance maintenance of the storage device 50. In an embodiment, the background controller 220 may control the defective memory device to perform the background operation using the normal blocks included in the defective memory device. For example, the background operation may include wear leveling, garbage collection, read reclaim, or the like.

In an embodiment, the background controller 220 may control a backup operation for storing user data, which is stored in the normal blocks included in the defective memory device, in a normal memory device other than the defective memory device among the plurality of memory devices 100. In an embodiment, after the user data stored in the normal blocks included in the defective memory device is backed up to the normal memory device, the normal blocks included in the defective memory device may be allocated to the over-provisioning area.

FIG. 8 is a diagram illustrating the block information storage 211 of FIG. 7 according to an embodiment.

Referring to FIG. 8, the block information storage 211 may store the block information on the plurality of memory devices 100.

The block information may include status information indicating whether each memory block is a normal block or a bad block, and allocation information indicating whether the normal block is allocated to the user area or the over-provisioning area. In an embodiment, an initial value of the status information may be set to indicate the normal block.

In an embodiment, the block information may be managed in a memory device unit. In another embodiment, the block information may be managed in a plane unit in one memory device. In still another embodiment, the block information may be managed in a super block unit in one memory device.

In FIG. 8, status information of a first memory block BLK1 may indicate a bad block. Status information of a second memory block BLK2 may indicate a normal block and the allocation information thereof may indicate the user area. Status information of a third memory block BLK3 may indicate a normal block and the allocation information thereof may indicate the over-provisioning area.

In various embodiments, the block information may include one or more of address information of a memory block, program/erase count information, read count information, capacity information, and the like, in addition to the status information and the allocation information.

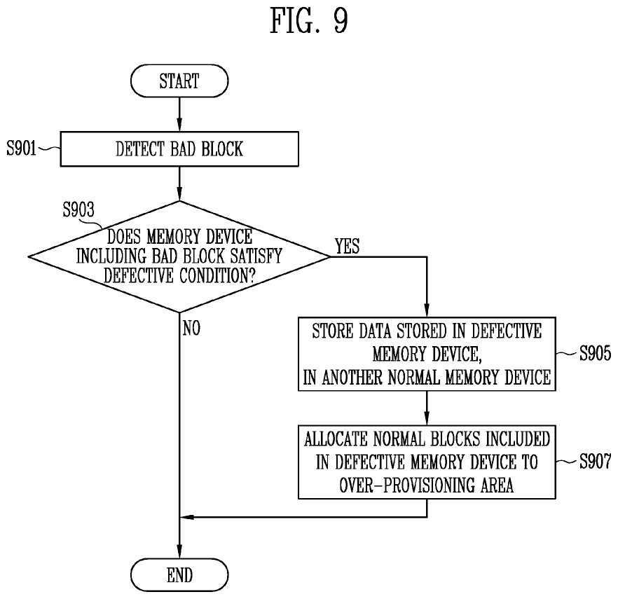

FIG. 9 is a flowchart for describing an operation of a storage device according to an embodiment. The storage device of FIG. 9 may correspond to the storage device 50 shown in FIGS. 1 and 7. The operation shown in FIG. 9 will be described with reference to the storage device 50 shown in FIG. 7.

Referring to FIG. 9, in step S901, the storage device 50 may detect a bad block. Specifically, the bad block detector 212 of the storage device 50 may detect the bad block among a plurality of memory blocks included in each of the plurality of memory devices 100. The bad block may be a memory block in which an uncorrectable error occurs while performing an overall operation on each of the plurality of memory blocks. The overall operation may include a read operation, a program operation, or an erase operation.

In step S903, the storage area setting component 213 of the storage device 50 may determine whether the memory device including the bad block satisfies a defective condition in order to determine whether the memory device is a defective memory device or not. As a determination result, when the memory device satisfies the defective condition, i.e., when the memory device is determined to be the defective memory device, the operation proceeds to step S905, and when the memory device does not satisfy the defective condition, the operation ends.

As described with reference to FIG. 6, in an embodiment, the defective condition may be satisfied when the number of bad blocks included in the memory device is equal to or greater than a first reference number. In another embodiment, the defective condition may be satisfied when the number of bad blocks included in any one of one or more planes included in the memory device is equal to or greater than a second reference number. In still another embodiment, the defective condition may be satisfied when the number of bad blocks included in any one of one or more super blocks included in the memory device is equal to or greater than a third reference number.

In an embodiment, each of the first to third reference numbers may be determined based on a reference ratio of the bad blocks to all memory blocks included in a reference area.

In an embodiment, the first to third reference numbers may be preset in a manufacturing stage. The first to third reference numbers may be updated or changed according to a request of the host 300 or a degree at which a lifetime of the storage device 50 is elapsed in a use stage.

In an embodiment, the bad block may be determined based on at least one of a manufacturing bad block (MBB) and a growing bad block (GBB).

In step S905, the background controller 220 of the storage device 50 may perform a backup operation for storing data, which is stored in normal blocks included in the defective memory device, in another normal memory device. When the defective memory device is detected in a test stage of the memory devices 100, the storage device 50 may not perform the backup operation.

In step S907, the storage area setting component 213 of the storage device 50 may allocate the normal blocks included in the defective memory device to an over-provisioning area.

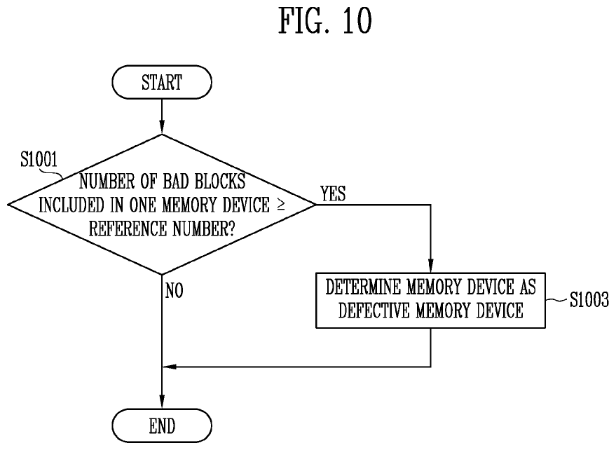

FIG. 10 is a flowchart for describing an operation of detecting a defective memory device according to a first embodiment.

Referring to FIG. 10, in step S1001, the storage device 50 may determine whether the number of bad blocks included in a memory device is equal to or greater than a first reference number. As a determination result, when the number of bad blocks is equal to or greater than the first reference number, the operation proceeds to step S1003, and when the number of bad blocks is less than the first reference number, the operation ends.

In step S1003, the storage device 50 may determine the memory device as a defective memory device.

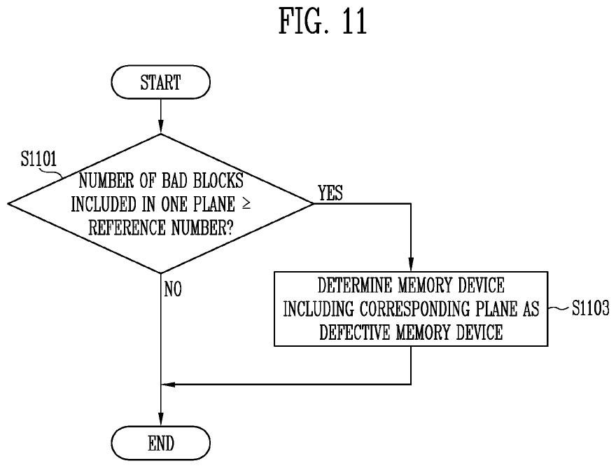

FIG. 11 is a flowchart for describing an operation of detecting a defective memory device according to a second embodiment.

Referring to FIG. 11, in step S1101, the storage device 50 may determine whether the number of bad blocks included in any one of one or more planes included in a memory device is equal to or greater than a second reference number. As a determination result, when the number of bad blocks is equal to or greater than the second reference number, the operation proceeds to step S1103, and when the number of bad blocks is less than the second reference number, the operation ends.

In step S1103, the storage device may determine the memory device including a corresponding plane as a defective memory device.

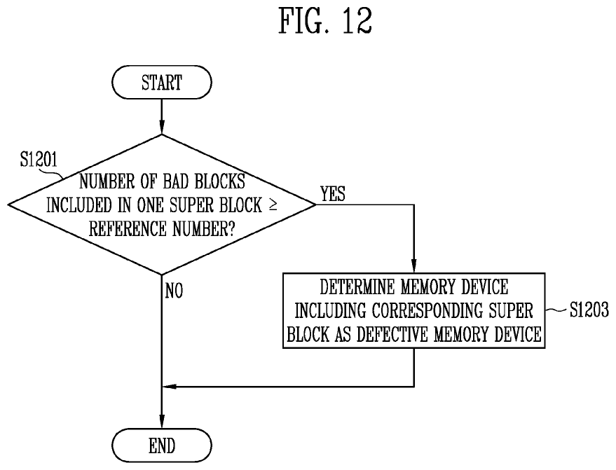

FIG. 12 is a flowchart illustrating an operation of detecting a defective memory device according to a third embodiment.

Referring to FIG. 12, in step S1201, the storage device 50 may determine whether the number of bad blocks included in any one of one or more super blocks included in a memory device is equal to or greater than a third reference number. As a determination result, when the number of bad blocks is equal to or greater than the third reference number, the operation proceeds to step S1203, and when the number of bad blocks is less than the third reference number, the operation ends.

In step S1203, the storage device 50 may determine the memory device including a corresponding super block as a defective memory device.

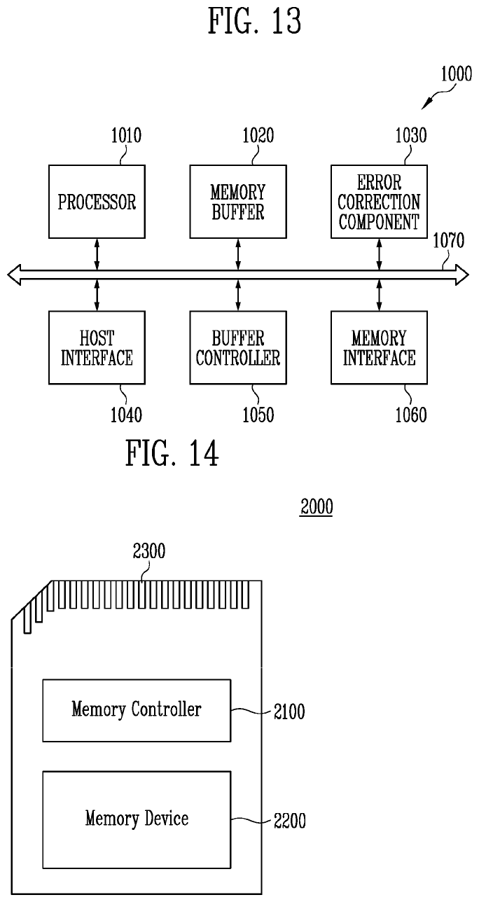

FIG. 13 is a diagram illustrating the memory controller 200 of FIG. 1 according to another embodiment.

Referring to FIG. 13, a memory controller 1000 is connected to the host 300 of FIG. 1 and the plurality of memory devices 100 of FIG. 1. The memory controller 1000 is configured to access the memory devices 100 in response to a request from the host 300. For example, the memory controller 1000 is configured to control write, read, erase, and background operations of the memory devices 100. The memory controller 1000 is configured to provide an interface between the memory devices 100 and the host 300. The memory controller 1000 is configured to drive firmware for controlling the memory devices 100.

The memory controller 1000 may include a processor 1010, a memory buffer 1020, an error correction component (ECC) 1030, a host interface 1040, a buffer controller 1050, a memory interface 1060, and a bus 1070.

The bus 1070 may be configured to provide a channel between components of the memory controller 1000.

The processor 1010 may control an overall operation of the memory controller 1000 and may perform a logical operation. The processor 1010 may communicate with the host 300 through the host interface 1040 and communicate with the memory devices 100 through the memory interface 1060. In addition, the processor 1010 may communicate with the memory buffer 1020 through the buffer controller 1050. The processor 1010 may control an operation of the storage device 50 using the memory buffer 1020 as an operation memory, a cache memory, or a buffer memory.

The processor 1010 may perform a function of a flash translation layer (FTL). The processor 1010 may convert a logical block address (LBA) provided by the host 300 into a physical block address (PBA) through the flash translation layer (FTL). The flash translation layer (FTL) may receive the logical block address (LBA) and convert the logical block address (LBA) into the physical block address (PBA) using a mapping table. An address mapping method of the flash translation layer (FTL) may include various methods according to a mapping unit. A representative address mapping method includes any of a page mapping method, a block mapping method, and a hybrid mapping method.

The processor 1010 is configured to randomize data received from the host 300. For example, the processor 1010 may randomize the data received from the host 300 using a randomizing seed. The randomized data is provided to the memory device 100 as data to be stored and is programmed to a memory cell array in the memory device 100.

The processor 1010 is configured to de-randomize data received from the memory device 100 during the read operation. For example, the processor 1010 may de-randomize the data received from the memory device 100 using a de-randomizing seed. The de-randomized data may be output to the host 300.

In an embodiment, the processor 1010 may perform the randomization and the de-randomization by driving software or firmware.

The memory buffer 1020 may be used as an operation memory, a cache memory, or a buffer memory of the processor 1010. The memory buffer 1020 may store codes and commands executed by the processor 1010. The memory buffer 1020 may store data processed by the processor 1010. The memory buffer 1020 may include a static RAM (SRAM) or a dynamic RAM (DRAM).

The ECC 1030 may perform error correction. The ECC 1030 may perform error correction encoding (ECC encoding) based on data to be written to the memory device 100 through memory interface 1060. The error correction encoded data may be transferred to the memory device 100 through the memory interface 1060. The ECC 1030 may perform error correction decoding (ECC decoding) on data received from the memory device 100 through the memory interface 1060. For example, the ECC 1030 may be included in the memory interface 1060 as a component of the memory interface 1060.

The host interface 1040 is configured to communicate with the host 300 under the control of the processor 1010. The host interface 1040 may be configured to perform communication using at least one of various communication methods such as a universal serial bus (USB), a serial AT attachment (SATA), a serial attached SCSI (SAS), a high speed interchip (HSIC), a small computer system interface (SCSI), a peripheral component interconnection (PCI express), a nonvolatile memory express (NVMe), a universal flash storage (UFS), a secure digital (SD), a multimedia card (MMC), an embedded MMC (eMMC), a dual in-line memory module (DIMM), a registered DIMM (RDIMM), and a load reduced DIMM (LRDIMM).

The buffer controller 1050 is configured to control the memory buffer 1020 under the control of the processor 1010.

The memory interface 1060 is configured to communicate with the memory device 100 under the control of the processor 1010. The memory interface 1060 may communicate a command, an address, and data with the memory device 100 through a channel.

In an embodiment, the memory buffer 1020 and the buffer controller 1050 may not be disposed within the memory controller 1000.

In an embodiment, the processor 1010 may control an operation of the memory controller 1000 using codes. The processor 1010 may load the codes from a non-volatile memory device (for example, a read only memory) provided inside the memory controller 1000. In another embodiment, the processor 1010 may load the codes from the memory device 100 through the memory interface 1060.

The bus 1070 of the memory controller 1000 may include a control bus and a data bus. The data bus may be configured to transmit data within the memory controller 1000 and the control bus may be configured to transmit control information such as a command and an address within the memory controller 1000. The data bus and the control bus may be separated from each other so that they may not interfere with each other or affect each other. The data bus may be connected to the host interface 1040, the buffer controller 1050, the ECC 1030, and the memory interface 1060. The control bus may be connected to the host interface 1040, the processor 1010, the buffer controller 1050, the memory buffer 1020, and the memory interface 1060.

FIG. 14 is a block diagram illustrating a memory card system 2000 to which the storage device according to an embodiment of the present disclosure is applied.

Referring to FIG. 14, the memory card system 2000 includes a memory controller 2100, a memory device 2200, and a connector 2300.

The memory controller 2100 is connected to the memory device 2200. The memory controller 2100 is configured to access the memory device 2200. For example, the memory controller 2100 may be configured to control read, write, erase, and background operations of the memory device 2200. The memory controller 2100 is configured to provide an interface between the memory device 2200 and a host. The memory controller 2100 is configured to drive firmware for controlling the memory device 2200. The memory controller 2100 may correspond to the memory controller 200 described with reference to FIG. 1.

The memory controller 2100 may include components such as a random access memory (RAM), a processor, a host interface, a memory interface, and an ECC.

The memory controller 2100 may communicate with an external device, e.g., the host, through the connector 2300. The memory controller 2100 may communicate with the external device according to a specific communication standard. For example, the memory controller 2100 is configured to communicate with the external device using at least one of various communication standards such as a universal serial bus (USB), a multimedia card (MMC), an embedded MMC (MCM), a peripheral component interconnection (PCI), a PCI express (PCI-E), an advanced technology attachment (ATA), a serial-ATA, a parallel-ATA, a small computer system interface (SCSI), an enhanced small disk interface (ESDI), integrated drive electronics (IDE), FireWire, a universal flash storage (UFS), Wi-Fi, Bluetooth, and an NVMe. For example, the connector 2300 may be defined by at least one of the various communication standards described above.

The memory device 2200 may be configured of various non-volatile memory devices such as an electrically erasable and programmable ROM (EEPROM), a NAND flash memory, a NOR flash memory, a phase-change RAM (PRAM), a resistive RAM (ReRAM), a ferroelectric RAM (FRAM), a spin-torque magnetic RAM (STT-MRAM), and so on.

The memory controller 2100 and the memory device 2200 may be integrated into one semiconductor device to configure a memory card such as a PC card (personal computer memory card international association (PCMCIA)), a compact flash card (CF), a smart media card (SM or SMC), a memory stick, a multimedia card (MMC, RS-MMC, MMCmicro, or eMMC), an SD card (SD, miniSD, microSD, or SDHC), a universal flash storage (UFS), or the like.

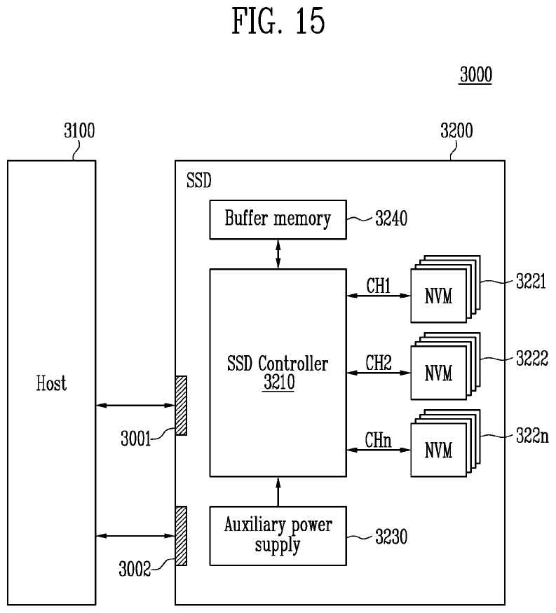

FIG. 15 is a block diagram illustrating a solid state drive SSD) system 3000 to which the storage device according to an embodiment of the present disclosure is applied.

Referring to FIG. 15, the SSD system 3000 includes a host 3100 and an SSD 3200. The SSD 3200 exchanges a signal SIG with the host 3100 through a signal connector 3001 and receives power PWR through a power connector 3002. The SSD 3200 includes an SSD controller 3210, a plurality of flash memories 3221 to 322n, an auxiliary power device 3230, and a buffer memory 3240.

According to an embodiment of the present disclosure, the SSD controller 3210 may perform the function of the memory controller 200 described with reference to FIG. 1.

The SSD controller 3210 may control the plurality of flash memories 3221 to 322n in response to the signal SIG received from the host 3100. For example, the signal SIG may be signals based on an interface between the host 3100 and the SSD 3200. For example, the signal SIG may be a signal defined by at least one of interfaces such as a universal serial bus (USB), a multimedia card (MMC), an embedded MMC (MCM), a peripheral component interconnection (PCI), a PCI express (PCI-E), an advanced technology attachment (ATA), a serial-ATA, a parallel-ATA, a small computer system interface (SCSI), an enhanced small disk interface (ESDI), integrated drive electronics (IDE), FireWire, a universal flash storage (UFS), Wi-Fi, Bluetooth, and an NVMe.

The auxiliary power device 3230 is connected to the host 3100 through the power connector 3002. The auxiliary power device 3230 may receive the power PWR from the host 3100 and may charge the power. The auxiliary power device 3230 may provide power of the SSD 3200 when power supply from the host 3100 is not smooth. For example, the auxiliary power device 3230 may be positioned in the SSD 3200 or may be positioned outside the SSD 3200. For example, the auxiliary power device 3230 may be positioned on a main board and may provide auxiliary power to the SSD 3200.

The buffer memory 3240 operates as a buffer memory of the SSD 3200. For example, the buffer memory 3240 may temporarily store data received from the host 3100 or data received from the plurality of flash memories 3221 to 322n, or may temporarily store metadata (for example, a mapping table) of the flash memories 3221 to 322n. The buffer memory 3240 may include a volatile memory such as a DRAM, an SDRAM, a DDR SDRAM, an LPDDR SDRAM, and a GRAM, or a non-volatile memory such as an FRAM, a ReRAM, an STT-MRAM, and a PRAM.

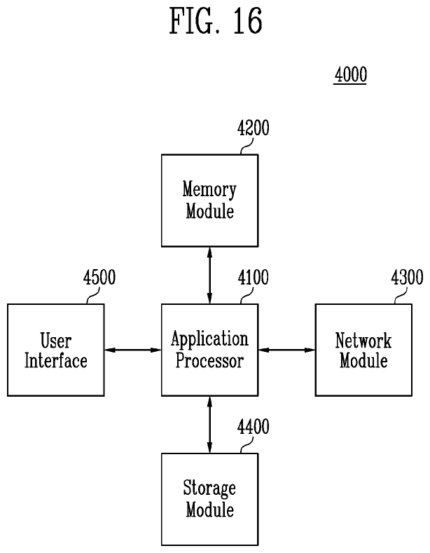

FIG. 16 is a block diagram illustrating a user system 4000 to which the storage device according to an embodiment of the present disclosure is applied.

Referring to FIG. 16, the user system 4000 includes an application processor 4100, a memory module 4200, a network module 4300, a storage module 4400, and a user interface 4500.

The application processor 4100 may drive components, an operating system (OS), a user program, or the like included in the user system 4000. For example, the application processor 4100 may include controllers, interfaces, graphics engines, and the like that control the components included in the user system 4000. The application processor 4100 may be provided as a system-on-chip (SoC).

The memory module 4200 may operate as a main memory, an operation memory, a buffer memory, or a cache memory of the user system 4000. The memory module 4200 may include a volatile random access memory such as a DRAM, an SDRAM, a DDR SDRAM, a DDR2 SDRAM, a DDR3 SDRAM, an LPDDR SDARM, an LPDDR2 SDRAM, and an LPDDR3 SDRAM, or a non-volatile random access memory, such as a PRAM, a ReRAM, an MRAM, and an FRAM. For example, the application processor 4100 and memory module 4200 may be packaged based on a package on package (POP) and provided as one semiconductor package.

The network module 4300 may communicate with external devices. For example, the network module 4300 may support wireless communication such as code division multiple access (CDMA), global system for mobile communications (GSM), wideband CDMA (WCDMA), CDMA-2000, time division multiple access (TDMA), long term evolution, Wimax, WLAN, UWB, Bluetooth, and Wi-Fi. For example, the network module 4300 may be included in the application processor 4100.

The storage module 4400 may store data. For example, the storage module 4400 may store data received from the application processor 4100. Alternatively, the storage module 4400 may transmit data stored in the storage module 4400 to the application processor 4100. For example, the storage module 4400 may be implemented as a non-volatile semiconductor memory element such as a phase-change RAM (PRAM), a magnetic RAM (MRAM), a resistive RAM (RRAM), a NAND flash, a NOR flash, and a three-dimensional NAND flash. For example, the storage module 4400 may be provided as a removable storage device (removable drive), such as a memory card, and an external drive of the user system 4000.

For example, the storage module 4400 may include a plurality of non-volatile memory devices, and the plurality of non-volatile memory devices may operate identically to the memory device 100 described with reference to FIG. 1. The storage module 4400 may operate identically to the storage device 50 described with reference to FIG. 1.

The user interface 4500 may include interfaces for inputting data or an instruction to the application processor 4100 or for outputting data to an external device. For example, the user interface 4500 may include user input interfaces such as a keyboard, a keypad, a button, a touch panel, a touch screen, a touch pad, a touch ball, a camera, a microphone, a gyroscope sensor, a vibration sensor, and a piezoelectric element. The user interface 4500 may include user output interfaces such as a liquid crystal display (LCD), an organic light emitting diode (OLED) display device, an active matrix OLED (AMOLED) display device, an LED, a speaker, and a monitor.

While various embodiments have been described above, it will be understood to those skilled in the art that the embodiments described are by way of example only. Accordingly, the storage device and the memory device described herein should not be limited based on the described embodiments.

What is claimed is:

1. A storage device, comprising:
a plurality of memory devices each including a plurality of memory blocks; and
a memory controller configured to detect a defective memory device among the plurality of memory devices and allocate normal blocks included in the defective memory device to an over-provisioning area used to perform a background operation on the plurality of memory devices.

2. The storage device of claim 1, wherein the memory controller comprises:
a storage area manager configured to allocate normal blocks included in each of the plurality of memory devices to a user area storing user data or the over-provisioning area, and detect the defective memory device satisfying a defective condition among the plurality of memory devices; and
a background controller configured to perform the background operation on the plurality of memory devices using the normal blocks included in the defective memory device.

3. The storage device of claim 2, wherein the storage area manager comprises:
a block information storage configured to store block information related to the plurality of memory blocks included in each of the plurality of memory devices;
a bad block detector configured to detect a bad block among the plurality of memory blocks included in each of the plurality of memory devices, and update the block information based on a result of detecting the bad block; and
a storage area setting component configured to detect the defective memory device among the plurality of memory devices based on the block information.

4. The storage device of claim 3, wherein the block information includes status information and allocation information, the status information indicating whether a memory block is a normal block or a bad block, the allocation information indicating whether the memory block is allocated to the user area or the over-provisioning area.

5. The storage device of claim 4, wherein when the defective memory device is detected, the storage area setting component updates allocation information corresponding to the normal blocks included in the defective memory device so that the normal blocks included in the defective memory device are allocated to the over-provisioning area.

6. The storage device of claim 3, wherein when an error uncorrectable block occurs while performing various operations on the plurality of memory blocks, the bad block detector detects the error uncorrectable block as the bad block.

7. The storage device of claim 2, wherein the background controller performs a backup operation of storing user data stored in the normal blocks included in the defective memory device in a normal memory device other than the defective memory device among the plurality of memory devices.

8. The storage device of claim 2, wherein the defective condition is that the number of bad blocks included in a memory device is equal to or greater than a reference number.

9. The storage device of claim 2, wherein each of the plurality of memory devices includes at least one plane, and
the defective condition is that the number of bad blocks included in any one of the at least one plane included in the memory device is equal to or greater than a reference number.

10. The storage device of claim 2, wherein each of the plurality of memory devices includes at least one super block and a plurality of planes, and
the defective condition is that the number of bad blocks in any one of the at least one super block in the memory device is equal to or greater than a reference number, a super block including a plurality of memory blocks disposed in different planes of the memory device.

11. The storage device of claim 2, wherein the defective condition is determined based on a reference number, and the reference number is preset in a manufacturing stage of the storage device.

12. The storage device of claim 11, wherein the reference number is updated according to a request of a host or a degree at which a lifetime of the storage device is elapsed.

13. A method of operating a storage device including a plurality of memory devices each including a plurality of memory blocks, the method comprising:
detecting a defective memory device satisfying a defective condition among the plurality of memory devices; and
allocating normal blocks included in the defective memory device to an over-provisioning area used to perform a background operation on the plurality of memory devices.

14. The method of claim 13, wherein detecting the defective memory device comprises:
detecting a bad block among the plurality of memory blocks included in each of the plurality of memory devices;
updating block information related to the plurality of memory blocks included in each of the plurality of memory devices based on a result of detecting the bad block; and
detecting the defective memory device among the plurality of memory devices based on the block information related to the plurality of memory blocks.

15. The method of claim 14, wherein the block information includes status information and allocation information, the status information indicating whether a memory block is a normal block or a bad block, the allocation information indicating whether the memory block is allocated to a user area or the over-provisioning area, the user area storing user data.

16. The method of claim 15, wherein the allocating comprises updating allocation information corresponding to the normal blocks included in the defective memory device.

17. The method of claim 13, further comprising:
performing a backup operation of storing user data stored in the normal blocks included in the defective memory device in a normal memory device other than the defective memory device among the plurality of memory devices.

18. The method of claim 13, wherein the defective condition is that the number of bad blocks included in a memory device is equal to or greater than a reference number.

19. The method of claim 13, wherein each of the plurality of memory devices includes at least one plane, and
the defective condition is that the number of bad blocks included in any one of the at least one plane included in a memory device is equal to or greater than a reference number.

20. The method of claim 13, wherein the defective condition is determined based on a reference number, and the reference number is preset in a manufacturing stage of the storage device and updated according to a request of a host or a degree at which a lifetime of the storage device is elapsed.
